(19) United States
(12) Patent Application Publication
(10) Pub. No.: US 2026/0060076 A1
(43) Pub. Date: Feb. 26, 2026

(54) SEMICONDUCTOR PACKAGE

(71) Applicant: Samsung Electronics Co., Ltd., Suwon-si (KR)

(72) Inventors: Gyunghwan OH, Suwon-si (KR); Dongwoon PARK, Suwon-si (KR)

(73) Assignee: Samsung Electronics Co., Ltd., Suwon-si (KR)

(21) Appl. No.: 19/056,101

(22) Filed: Feb. 18, 2025

(30) Foreign Application Priority Data
Aug. 21, 2024 (KR) 10-2024-0112348

(51) Int. Cl. H01L 23/367; H01L 23/00; H01L 23/31; H01L 23/373; H01L 23/498; H01L 23/538; H01L 25/16; H10B 80/00; H10D 80/30

(52) U.S. Cl. CPC H01L 23/3677; H01L 23/3128; H01L 23/373; H01L 23/49838; H01L 23/5385; H01L 25/16; H10B 80/00; H10D 80/30; H01L 24/16; H01L 24/32; H01L 24/73; H01L 2224/16227; H01L 2224/16238; H01L 2224/32225; H01L 2224/73204; H01L 2225/06517; H01L 2225/06589; H01L 2924/1431

(57) ABSTRACT

Provided is a semiconductor package including a first semiconductor device, an encapsulant surrounding the first semiconductor device, an upper redistribution structure provided on the encapsulant, and a heat dissipation block provided on the upper redistribution structure. The heat dissipation block includes a first block surface facing a top surface of the upper redistribution structure, the heat dissipation block includes a first protrusion on the first block surface, a first concave portion corresponding to the first protrusion is provided on the top surface of the upper redistribution structure, the first protrusion is located in the first concave portion, and a heat transfer layer is provided between the heat dissipation block and the top surface of the upper redistribution structure.

### CROSS-REFERENCE TO RELATED APPLICATION

This application is based on and claims priority under 35 U.S.C. § 119 to Korean Patent Application No. 10-2024-0112348, filed on Aug. 21, 2024, in the Korean Intellectual Property Office, the disclosure of which is incorporated by reference herein in its entirety.

### BACKGROUND

The inventive concept relates to a semiconductor package, and more particularly, to a semiconductor package including a heat dissipation block.

In accordance with the rapid development of the electronics industry and the demands of users, electronic devices are becoming more compact, multifunctional, and large-capacity, and accordingly, highly integrated semiconductor chips are required. Therefore, for highly integrated semiconductor chips with an increased number of connection terminals for input/output (I/O), a semiconductor package having connection terminals with secured connection reliability is being designed, for example, a fan-out semiconductor package with increased spacing between connection terminals is being developed in order to prevent interference between the connection terminals.

In order to improve the thermal characteristics of the semiconductor package to facilitate heat dissipation, a semiconductor package including a heat dissipation block has been used. When the heat dissipation block is arranged on the semiconductor package, the heat dissipation block may be arranged on the semiconductor package without being aligned.

### SUMMARY

The inventive concept provides a semiconductor package in which heat dissipation blocks are aligned and arranged at an intended position in the semiconductor package, to improve the heat dissipation performance of the semiconductor package.

The task to be solved by the technical idea of the inventive concept is not limited to the above-mentioned task, and other tasks not mentioned may be clearly understood by those of ordinary skill in the art from the following description.

According to an aspect of the inventive concept, there is provided a semiconductor package including a first semiconductor device, an encapsulant surrounding the first semiconductor device, an upper redistribution structure provided on the encapsulant, and a heat dissipation block provided on the upper redistribution structure. The heat dissipation block includes a first block surface facing a top surface of the upper redistribution structure, the heat dissipation block includes a first protrusion on the first block surface, a first concave portion corresponding to the first protrusion is provided on the top surface of the upper redistribution structure, the first protrusion is located in the first concave portion, and a heat transfer layer is provided between the heat dissipation block and the top surface of the upper redistribution structure.

In addition, according to another aspect of the inventive concept, there is provided a semiconductor package including a lower redistribution structure, a first semiconductor device arranged on the lower redistribution structure, a plurality of conductive posts laterally spaced apart from the first semiconductor device and provided on the lower redistribution structure, an encapsulant surrounding the first semiconductor device and the plurality of conductive posts, an upper redistribution structure provided on the encapsulant, a heat dissipation block provided on the upper redistribution structure, and a second semiconductor device laterally spaced apart from the heat dissipation block and arranged on the upper redistribution structure. The heat dissipation block includes a first block surface facing a top surface of the upper redistribution structure, the heat dissipation block includes at least one first protrusion on the first block surface, at least one first concave portion corresponding to the first protrusion is provided on the top surface of the upper redistribution structure, the first protrusion is located in the first concave portion, and a heat transfer layer is provided between the heat dissipation block and the top surface of the upper redistribution structure.

In addition, according to another aspect of the inventive concept, there is provided a semiconductor package including a lower redistribution structure, a first semiconductor device arranged on the lower redistribution structure, a plurality of conductive posts laterally spaced apart from the first semiconductor device and provided on the lower redistribution structure, an encapsulant surrounding the first semiconductor device and the plurality of conductive posts, an upper redistribution structure provided on the encapsulant, a heat dissipation block provided on the upper redistribution structure, and a second semiconductor device laterally spaced apart from the heat dissipation block and arranged on the upper redistribution structure. The heat dissipation block includes a first block surface facing a top surface of the upper redistribution structure, the heat dissipation block includes at least one first protrusion on the first block surface, at least one first concave portion corresponding to the first protrusion is provided on the top surface of the upper redistribution structure, the first protrusion is located in the first concave portion, and a heat transfer layer is provided between the heat dissipation block and the top surface of the upper redistribution structure, at least a portion of the heat dissipation block overlaps the first semiconductor device perpendicularly, the second semiconductor device overlaps at least a portion of the plurality of conductive posts perpendicularly, the upper redistribution structure includes a plurality of redistribution insulating layers, a first depth of the first concave portion is equal to or less than a first thickness, which is a thickness of an uppermost first upper redistribution insulating layer among the plurality of redistribution insulating layers, a first height of the first protrusion is equal to or less than the first depth of the first concave portion, the first depth of the first concave portion is defined as a depth recessed downward from the top surface of the upper redistribution structure of the first concave portion, the first height of the first protrusion is defined as a height of the first protrusion from the first block surface, the first concave portion has a shape complementary to a shape of the first protrusion, the first protrusion is integrally formed with the heat dissipation block, and a shape of the vertical cross-section of the first protrusion is a portion of an oval.

### BRIEF DESCRIPTION OF THE DRAWINGS

Embodiments will be more clearly understood from the following detailed description taken in conjunction with the accompanying drawings in which:

FIG. 1A is a cross-sectional view of a semiconductor package according to embodiments;

FIG. 1B is a perspective view of a semiconductor package according to embodiments;

FIG. 1C is a plan view of a semiconductor package according to embodiments;

FIG. 2A is a cross-sectional view of a semiconductor package according to embodiments;

FIG. 2B is a plan view of a semiconductor package according to embodiments;

FIG. 3 is a plan view of a semiconductor package according to embodiments;

FIG. 4 is a cross-sectional view of a semiconductor package according to embodiments;

FIG. 5 is a cross-sectional view of a semiconductor package according to embodiments; and

FIG. 6 is a cross-sectional view of a semiconductor package according to embodiments.

### DETAILED DESCRIPTION OF THE EMBODIMENTS

Hereinafter, embodiments of the technical idea of the inventive concept will be described in detail with reference to the accompanying drawings.

Embodiments of the technical idea of the inventive concept are provided to more completely explain the technical idea of the inventive concept to one of ordinary skill in the art, and the following embodiments may be modified in various different forms, and the scope of the technical idea of the inventive concept is not limited to the following embodiments. Rather, these embodiments are provided to make the present disclosure more faithful and complete, and to fully convey the spirit of the inventive concept to one of ordinary skill in the art. In addition, the thickness or size of each layer in the drawings is exaggerated for convenience and clarity of explanation.

In the present specification, the first direction may refer to an X-direction, the second direction may refer to a Y-direction, and the first direction and the second direction may be perpendicular to each other. The third direction may be a Z-direction, and the third direction may be perpendicular to each of the first direction and the second direction. A horizontal plane or plane refers to an X-Y plane. The top surface of a specific object means one surface positioned in a positive third direction with respect to the specific object, and the bottom surface of the specific object means one surface positioned in a negative third direction with respect to the specific object.

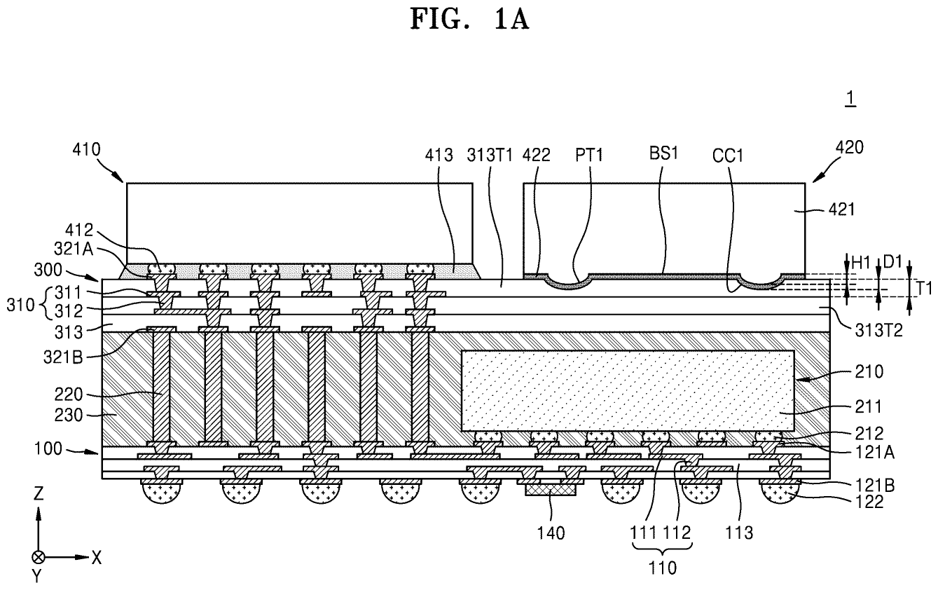

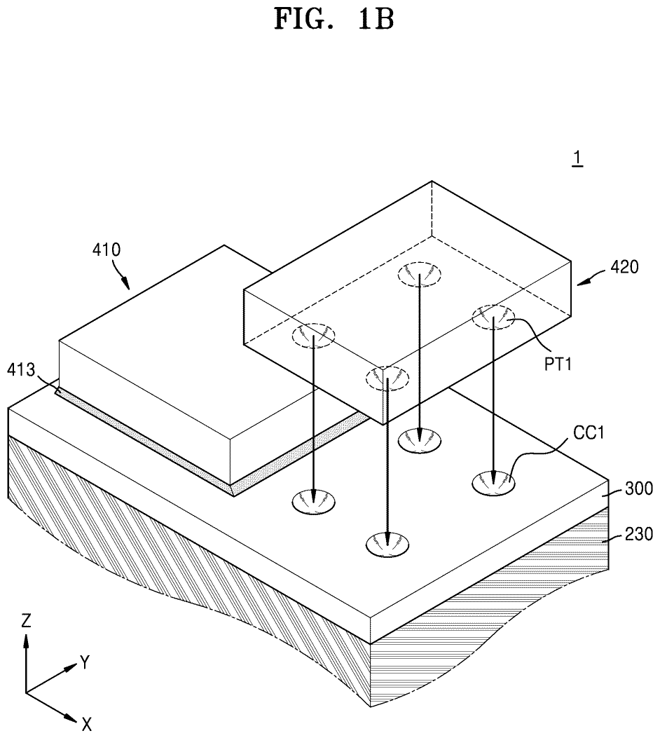

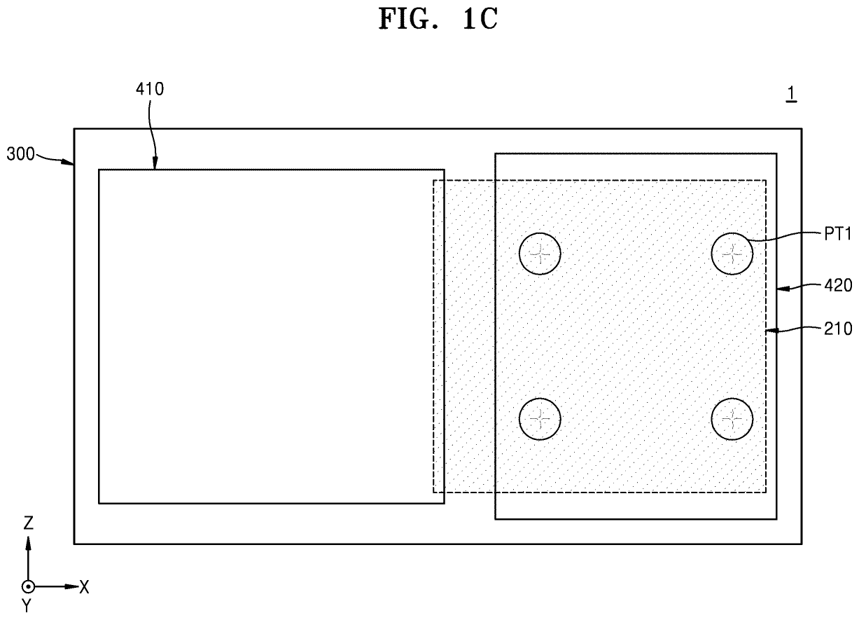

FIG. 1A is a cross-sectional view of a semiconductor package 1 according to embodiments. FIG. 1B is a perspective view of a semiconductor package 1 according to embodiments. FIG. 1C is a plan view of a semiconductor package 1 according to embodiments.

Referring to FIGS. 1A to 1C, a semiconductor package 1 may include a lower redistribution structure 100, a first semiconductor device 210 mounted on the lower redistribution structure 100, a plurality of conductive posts 220 laterally spaced apart from the first semiconductor device 210, an encapsulant 230 surrounding the side surface of the plurality of conductive posts 220 and the first semiconductor device 210, an upper redistribution structure 300 provided on the encapsulant 230 and electrically connected to the plurality of conductive posts 220, a second semiconductor device 410 provided on the upper redistribution structure 300, and a heat dissipation block 420 provided on the upper redistribution structure 300.

The semiconductor package 1 may be a fan out semiconductor package in which the width and area of the lower redistribution structure 100 in the horizontal direction are larger than the width and area horizontally configured by the first semiconductor device 210. In embodiments, the semiconductor package 1 may be a fan out wafer level package (FOWLP) or a fan out panel level package (FOPLP). An embodiment in which the semiconductor package is a fan-out panel level package will be described later.

In some embodiments, the lower redistribution structure 100 may be formed by a redistribution process. The lower redistribution structure 100 may include a plurality of lower redistribution insulating layers 113 and a plurality of lower redistribution patterns 110. The plurality of lower redistribution insulating layers 113 may surround the plurality of lower redistribution patterns 110. In some embodiments, the lower redistribution structure 100 may include the plurality of stacked lower redistribution insulation layers 113. The plurality of lower redistribution insulation layers 113 may include, for example, a photo imageable dielectric (PID) or a photosensitive polyimide (PSPI). According to some embodiments, a passivation layer may be provided on a bottom surface of the lower redistribution structure 100. The passivation layer protecting the lower redistribution structure 100 may include a polymer, and may cover at least a portion of a side surface and a bottom surface of each of a plurality of external connection pads 121B.

The plurality of lower redistribution patterns 110 may include a plurality of lower redistribution line patterns 111 and a plurality of lower redistribution via patterns 112. The plurality of lower redistribution patterns 110 may be, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru) or the like, or a metal alloy thereof, but are not limited thereto.

The plurality of lower redistribution line patterns 111 may be arranged on at least one of a top surface and a bottom surface of the plurality of lower redistribution insulating layers 113. For example, when the lower redistribution structure 100 includes the plurality of stacked lower redistribution insulating layers 113, the plurality of lower redistribution line patterns 111 may be arranged on the bottom surface of the uppermost lower redistribution insulating layer of the plurality of lower redistribution insulating layers 113, on the top surface of the lowermost lower redistribution insulating layer of the plurality of lower redistribution insulating layers 113, and between the neighboring lower redistribution insulating layers 113.

The plurality of lower redistribution via patterns 112 may penetrate the plurality of lower redistribution insulating layers 113 to be connected to some of the plurality of lower redistribution line patterns 111. In some embodiments, the plurality of lower redistribution via patterns 112 each may have a tapered shape in which the horizontal width decreases and extends as the distance from the encapsulant 230 increases.

In some embodiments, some of the plurality of lower redistribution line patterns 111 may be formed together with some of the plurality of redistribution via patterns 112 to form an integral part. For example, the plurality of lower redistribution line patterns 111 and the plurality of lower redistribution via patterns 112 in contact with the bottom surfaces of the plurality of lower redistribution line patterns 111 may be formed together to be integrated.

Among the plurality of lower redistribution patterns 110, portions arranged adjacent to the bottom surface of the lower redistribution structure 100 may be referred to as a plurality of external connection pads 121B, and portions arranged adjacent to the top surface of the lower redistribution structure 100 may be referred to as a plurality of first upper connection pads 121A. The plurality of external connection pads 121B may be some of the plurality of lower redistribution line patterns 111 arranged adjacent to the bottom surface of the lower redistribution structure 100, and the plurality of first upper connection pads 121A may be some of the plurality of lower redistribution line patterns 111 arranged adjacent to the top surface of the lower redistribution structure 100.

A plurality of external connection terminals 122 may be attached to the plurality of external connection pads 121B. The plurality of external connection terminals 122 may connect the semiconductor package 1 to the outside. In some embodiments, the plurality of external connection terminals 122 may be solder bumps or solder balls. A plurality of first chip connection terminals 212 may be provided in some of the plurality of first upper connection pads 121A, and a plurality of conductive posts 220 may be provided in the remaining parts of the plurality of first upper connection pads 121A.

A passive element 140 may be provided in some of the plurality of external connection pads 121B. The passive element 140 may be electrically connected to the first semiconductor device 210 through the lower redistribution structure 100. The passive element 140 may include a capacitor, a resistor, an inductor, and the like, and a plurality of passive elements 140 may be provided in the lower redistribution structure 100.

The plurality of first upper connection pads 121A may be arranged on the top surface of a plurality of lower redistribution insulating layers 113. For example, when the lower redistribution structure 100 includes the plurality of stacked lower redistribution insulation layers 113, the plurality of first upper connection pads 121A may be arranged on the top surface of the uppermost lower redistribution insulation layer 113.

At least one first semiconductor device 210 may be provided on the lower redistribution structure 100. That is, the first semiconductor device 210 may include a single number of first semiconductor device or a plurality of first semiconductor devices. The first semiconductor device 210 may include a semiconductor substrate 211 and a plurality of first chip pads arranged on the bottom surface of the semiconductor substrate 211. For example, the first semiconductor device 210 may have a thickness of about 150μm or more in a vertical direction. In the present specification, the bottom surface of the first semiconductor device 210 refers to a surface facing the lower redistribution structure 100, and the top surface of the first semiconductor device 210 refers to a surface facing the upper redistribution structure 300. In some embodiments, an active surface in which elements are arranged in the first semiconductor device 210 has a face down arrangement facing the lower redistribution structure 100, and may be mounted on the top surface of the lower redistribution structure 100. A plurality of first chip pads may be provided on a bottom surface of the first semiconductor device 210, and the plurality of first chip pads may be connected to the plurality of first chip connection terminals 212, respectively.

The plurality of first chip connection terminals 212 may be provided between the plurality of first chip pads of the first semiconductor device 210 and the plurality of first upper connection pads 121A of the lower redistribution structure 100, respectively. For example, each of the plurality of first chip connection terminals 212 may be a solder ball or a microbump. The first semiconductor device 210 may be electrically connected with the plurality of lower redistribution patterns 110 of the lower redistribution structure 100 through the plurality of first chip connection terminals 212. The plurality of first chip connection terminals 212 may include, for example, copper (Cu), aluminum (Al), silver (Ag), tin (Tin), gold (Au), or solder, but are not limited thereto.

The semiconductor substrate 211 may include, for example, a semiconductor material such as silicon (Si) or germanium (Ge). Alternatively, the semiconductor substrate 211 may include a compound semiconductor material, such as silicon carbide (SiC), gallium arsenide (GaAs), indium arsenide (InAs), and indium phosphide (InP). The semiconductor substrate 211 may include a well doped with impurities as a conductive region. The semiconductor substrate 211 may have various device isolation structures such as a shallow trench isolation (STI) structure.

A semiconductor device including a plurality of types of individual devices may be formed on the active surface of the semiconductor substrate 211. The plurality of individual devices may be electrically connected to the conductive region of the semiconductor substrate 211. The semiconductor device may further include a conductive wiring or a conductive plug electrically connecting the plurality of individual devices with the conductive region of the semiconductor substrate 211. In addition, each of the plurality of individual devices may be electrically separated from other neighboring individual devices by an insulating layer.

In some embodiments, the first semiconductor device 210 may include a logic device. For example, the first semiconductor device 210 may be a central processing device chip, a graphic processing device chip, or an application processor chip. In other embodiments, when the semiconductor package 1 includes the plurality of first semiconductor devices 210, one of the plurality of first semiconductor devices 210 may be a central processing unit chip, a graphic processing unit chip, or an application processor chip, and the other may be a memory semiconductor chip including a memory device.

For example, the memory device may be a nonvolatile memory device, such as flash memory, phase-change random access memory (PRAM), magnetoresistive random access memory (MRAM), ferroelectric random access memory (FeRAM), or resistive random access memory (RRAM). In some embodiments, the memory device may be a volatile memory device, such as dynamic random access memory (DRAM) or static random access memory (SRAM).

In some embodiments, a first underfill layer surrounding the plurality of first chip connection members 212 may be located between the first semiconductor device 210 and the lower redistribution structure 100. In some embodiments, the first underfill layer fills a space between the first semiconductor device 210 and the lower redistribution structure 100, and may cover a portion of a lower side of the side surface of the first semiconductor device 210 or a bottom surface of the first semiconductor device 210. The first underfill layer may be formed by, for example, a capillary underfill process, and may include an epoxy resin.

The encapsulant 230 may surround the first semiconductor device 210 and the plurality of conductive posts 220 on the top surface of the lower redistribution structure 100. The top surface of the encapsulant 230 may be coplanar with one end surface of the plurality of conductive posts 220. This is due to the manufacturing process, because the top surface of the encapsulant 230 is polished by chemical mechanical polishing (CMP), and, in this case, the encapsulant 230 and the plurality of conductive posts 220 are simultaneously polished.

The encapsulant 230 may have a thickness of about 150μm to about 500μm. For example, the encapsulant 230 may be a molding member including an epoxy mold compound (EMC). The encapsulant 230 may further include a filler.

The upper redistribution structure 300 may be provided on the top surface of the encapsulant 230. The upper redistribution structure 300 may include a plurality of upper redistribution insulating layers 313 and a plurality of upper redistribution patterns 310. The plurality of upper redistribution insulation layers 313 may include, for example, a photo imageable dielectric (PID) or a photosensitive polyimide (PSPI). The plurality of upper redistribution patterns 310 may include a plurality of upper redistribution line patterns 311 and a plurality of upper redistribution via patterns 312. The upper redistribution structure 300 may be formed by a redistribution process.

The plurality of upper redistribution via patterns 312 may penetrate the plurality of upper redistribution insulating layers 313 to be connected to some of the plurality of upper redistribution line patterns 311. In some embodiments, the plurality of upper redistribution via patterns 312 each may have a tapered shape in which the horizontal width decreases and extends as the distance from the encapsulant 230 decreases. A detailed description of the upper redistribution structure 300 is substantially the same as that of the lower redistribution structure 100.

A plurality of second upper connection pads 321A may be provided on a top surface of the upper redistribution structure 300, and a plurality of second lower connection pads 321B may be provided on a bottom surface of the upper redistribution structure 300. Among the plurality of upper redistribution patterns 310, portions arranged on the bottom surface of the upper redistribution structure 300 may be referred to as a plurality of second lower connection pads 321B, and portions arranged on the top surface of the upper redistribution structure 300 may be referred to as a plurality of second upper connection pads 321A.

According to embodiments, a side surface of the lower redistribution structure 100, a side surface of the encapsulant 230, and a side surface of the upper redistribution structure 300 may be aligned in a vertical direction. The side surface of the lower redistribution structure 100, the side surface of the encapsulant 230, and the side surface of the upper redistribution structure 300 may be coplanar.

The plurality of conductive posts 220 penetrating through the encapsulant 230 may electrically connect the lower redistribution structure 100 with the upper redistribution structure 300. The encapsulant 230 may surround the side surfaces of the plurality of conductive posts 220.

The plurality of conductive posts 220 may be laterally spaced apart from the first semiconductor device 210 and arranged on the top surface of the lower redistribution structure 100. The plurality of conductive posts 220 may be provided between the lower redistribution structure 100 and the upper redistribution structure 300.

The plurality of conductive posts 220 may be electrically connected to the second semiconductor device 410 by the plurality of upper redistribution patterns 310 provided in the upper redistribution structure 300. In addition, the plurality of conductive posts 220 may be electrically connected to the first semiconductor device 210 by the plurality of lower redistribution patterns 110 provided in the lower redistribution structure 100. Therefore, the first semiconductor device 210 and the second semiconductor device 410 may be electrically connected with each other through the lower redistribution structure 100, the plurality of conductive posts 220, and the upper redistribution structure 300 to exchange electrical signals.

At least one second semiconductor device 410 may be provided on the upper redistribution structure 300. That is, a single second semiconductor device 410 or a plurality of second semiconductor devices 410 may be provided. The plurality of second chip pads may be provided on the bottom surface of the second semiconductor device 410. A plurality of second connection terminals 412 may be provided between the plurality of second chip pads and the plurality of second upper connection pads 321A, respectively.

In some embodiments, a second underfill layer 413 surrounding the plurality of first chip connection members 412 may be located between the second semiconductor device 410 and the upper redistribution structure 300. In some embodiments, the second underfill layer 413 fills a space between the second semiconductor device 410 and the upper redistribution structure 300, and may cover a portion of a lower side of the side surface of the second semiconductor device 410 or a bottom surface of the second semiconductor device 410. The second underfill layer 413 may be formed by, for example, a capillary underfill process, and may include an epoxy resin.

The second semiconductor device 410 may include one or more semiconductor chips. When the second semiconductor device 410 includes a plurality of semiconductor chips, the plurality of semiconductor chips may be stacked. The second semiconductor device 410 may include a logic device. For example, the second semiconductor device 410 may be a memory semiconductor chip including a memory device. For example, the memory device may be a nonvolatile memory device, such as flash memory, phase-change random access memory (PRAM), magnetoresistive random access memory (MRAM), ferroelectric random access memory (FeRAM), or resistive random access memory (RRAM). In some embodiments, the memory device may be a volatile memory device, such as dynamic random access memory (DRAM) or static random access memory (SRAM).

The second semiconductor device 410 may be a semiconductor device in which a plurality of semiconductor chips are vertically stacked. The plurality of semiconductor chips may be stacked semiconductor chips including a Through Silicon Via (TSV). For example, the second semiconductor device 410 may be a high bandwidth memory (HBM).

The heat dissipation block 420 may be laterally spaced apart from the second semiconductor device 410, and the heat dissipation block 420 may be provided on the upper redistribution structure 300. A heat transfer layer 422 may be arranged between the heat dissipation block 420 and the upper redistribution structure 300.

The heat dissipation block 420 may include a block body 421 and a first protrusion PT1 protruding downward from a first block surface BS1 corresponding to a bottom surface of the heat dissipation block 420. The first protrusion PT1 may be formed during a process of manufacturing the heat dissipation block 420. That is, the first protrusion PT1 may be integrally formed with the heat dissipation block body 421.

The first protrusion PT1 may protrude downward from the first block surface BS1 of the heat dissipation block 420. In embodiments, as shown in FIG. 1A, the shape of the vertical cross-section of the first block surface BS1 including the first protrusion PT1 may have an elliptical shape protruding downward. A plurality of first protrusions PT1 may be provided on the first block surface BS1, and each of the plurality of first protrusions PT1 may be positioned to be spaced apart from each other on the first block surface BS1. For example, as shown in FIG. 1B, four first protrusions PT1 may be provided on the first block surface BS1, and the four first protrusions PT1 may be arranged adjacent to each vertex of the rectangularly shaped first block surface BS1.

First concave portions CC1 may be provided on the top surface of the upper redistribution structure 300. The first concave portions CC1 may refer to grooves dug from the top surface of the upper redistribution structure 300 to the downside of the upper redistribution structure 300. The first concave portions CC1 may be provided on the top surface of the upper redistribution structure 300 to correspond to the first protruding portions PT1.

As described above, when the four first protrusions PT1 are provided on the first block surface BS1 of the heat dissipation block 420, the four first concave portions CC1 may be provided on the top surface of the upper redistribution structure 300 in the same manner. In addition, the four first protrusions PT1 provided in the heat dissipation block 420 may be inserted into the four corresponding first concave portions CC1.

Before the heat dissipation block 420 is arranged on the upper redistribution structure 300, the heat transfer layer 422 may be applied first on the upper redistribution structure 300. Therefore, the heat transfer layer 422 may be arranged along the shape of the top surface of the upper redistribution structure 300 including the first concave portions CC1 and the shape of the first block surface BS1 including the first protrusion portions PT1. For example, as shown in FIG. 1A, the heat transfer layer 422 may be arranged between the top surface of the upper redistribution structure 300 including the first concave portions CC1 and the first block surface BS1 including the first protrusion portions PT1.

A height to which the first protrusion PT1 protrudes from the first block surface BS1 may be defined as a first height H1, and a depth at which the first concave portion CC1 is recessed from the top surface of the upper redistribution structure 300 may be defined as a first depth D1. A plurality of upper redistribution insulating layers 313 may include a first upper redistribution insulating layer 313T1 positioned at the uppermost end among the plurality of upper redistribution insulating layers 313, and a second upper redistribution insulating layer 313T2, which is an upper redistribution insulating layer 313 positioned directly below the first upper redistribution insulating layer 313T1. A vertical thickness of the first upper redistribution insulating layer 313T1 may be defined as a first thickness T1.

The first concave portions CC1 may be formed together in the process of forming a plurality of openings in which the plurality of second upper connection pads 321A are provided on the upper redistribution structure 300. However, the plurality of second upper connection pads 321A may be formed in the plurality of openings, and a separate configuration may not be formed in the first concave portions CC1.

The first depth D1, which is the depth of the first concave portion CC1, may be substantially equal to or less than the first thickness T1, which is the thickness of the first upper redistribution insulating layer 313T1. That is, the first concave portions CC1 may be formed on the first upper redistribution insulating layer 313T1 positioned at the uppermost end among the plurality of upper redistribution insulating layers 313. For example, the first thickness T1 may be about 5μm to about 20μm, and the first depth D1 of the first concave portion CC1 may be about 3 μm to about 20μm. In one or more aspects, the term “being about a value” (“substantially,” “approximately,” etc.) may indicate “being a value” or being within an industry-accepted tolerance, due to a process error or a measurement error recognizable by one of ordinary skill in the art provide, for the corresponding term and/or relativity between items, such as a tolerance of ±1%, ±5%, or ±10% of the actual value stated, and other suitable tolerances.

The first height H1 of the first protrusion PT1 may be less than or substantially the same as the first depth D1 of the first concave portion CC1. In this case, when the first protrusion PT1 of the heat dissipation block 420 and the first concave portion CC1 correspond to each other and the first protrusion PT1 is located in the first concave portion CC1, the position of the heat dissipation block 420 may be aligned due to the shape in which the first protrusion PT1 and the first concave portion CC1 are engaged with each other. That is, due to the interlocking shapes of the first protrusions PT1 and the first concave portions CC1, the possibility of the heat dissipation block 420 being misaligned and placed on the upper redistribution structure 300 may be reduced. On the contrary, when the first height H1 of the first protrusion PT1 is greater than the first depth D1 of the first concave portion CC1, the first block surface BS1 of the heat dissipation block 420 may be spaced apart from the top surface of the upper redistribution structure 300, thereby reducing the efficiency of heat dissipation through the heat dissipation block 420.

The semiconductor package 1 according to embodiments may reduce the possibility that the heat dissipation block 420 is misaligned and arranged due to the heat dissipation block 420 having the first protrusions PT1 and the upper redistribution structure 300 having the first concave portions CC1. Since the heat dissipation block 420 may be aligned and arranged at an intended position, thermal characteristics of the semiconductor package 1 may be improved. In addition, since the heat dissipation block 420 is not misaligned, interference with the peripheral components of the semiconductor package 1 may not occur in the semiconductor package 1. In addition, the occurrence of problems in subsequent processes due to misalignment of the heat dissipation block 420 may be reduced.

In semiconductor packages other than this inventive concept, all of the plurality of upper redistribution insulating layers positioned on the encapsulant on which the heat dissipation block will be placed may be removed, and the heat dissipation block may be directly arranged on the encapsulant. In this case, cracks may occur in the plurality of upper redistribution insulating layers due to different thermal expansion coefficients between the heat dissipation block and the plurality of upper redistribution insulating layers. However, in the semiconductor package 1 according to embodiments, all of the upper redistribution structure 300 are not removed, but only a part of the upper redistribution insulating layer 313 adjacent to the top surface of the upper redistribution structure 300 is removed, and thus, cracks are significantly less likely to occur in the upper redistribution insulating layer 313. Therefore, heat dissipation characteristics may be improved, and reliability of the semiconductor package 1 may be improved.

The heat dissipation block 420 may be arranged above the first semiconductor device 210. In addition, as shown in FIG. 1C, at least a portion of the heat dissipation block 420 may overlap the first semiconductor device 210 in a vertical direction. This is mainly because placing the heat dissipation block 420 adjacent to the first semiconductor device 210 that generates heat is more effective in the heat dissipation characteristics of the semiconductor package 1.

The heat dissipation block 420 may include a metal including at least one of aluminum (Al), copper (Cu), titanium (Ti), nickel (Ni), iron (Fe), cobalt (Co), palladium (Pd), platinum (Pt), gold (Au), lead (Pb), silver (Ag), carbon (C), tin (Sn), tungsten (W), and chromium (Cr), or an alloy thereof.

The heat transfer layer 422 may include a thermal interface material (TIM). The heat transfer layer 422 may have a higher heat transfer rate than a general adhesive material. The heat transfer layer 422 fixes the heat dissipation block 420 on the upper redistribution structure 300, and simultaneously the heat transfer layer 422 may receive heat generated from the first semiconductor device 210 and transferred to the encapsulant 230 and the upper redistribution structure 300. In general, the heat transfer layer 422 may have a structure in which a filler such as metal particles is dispersed in a polymer material. For example, the heat dissipation interface material may include mineral oil, grease, gap filler putty, phase change gel, phase change material pads, or particle filled epoxy.

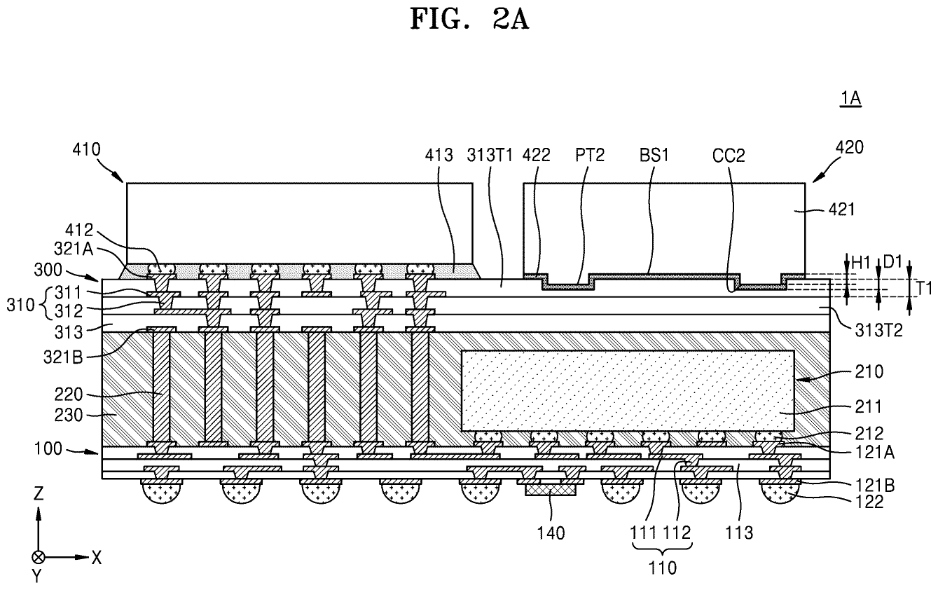

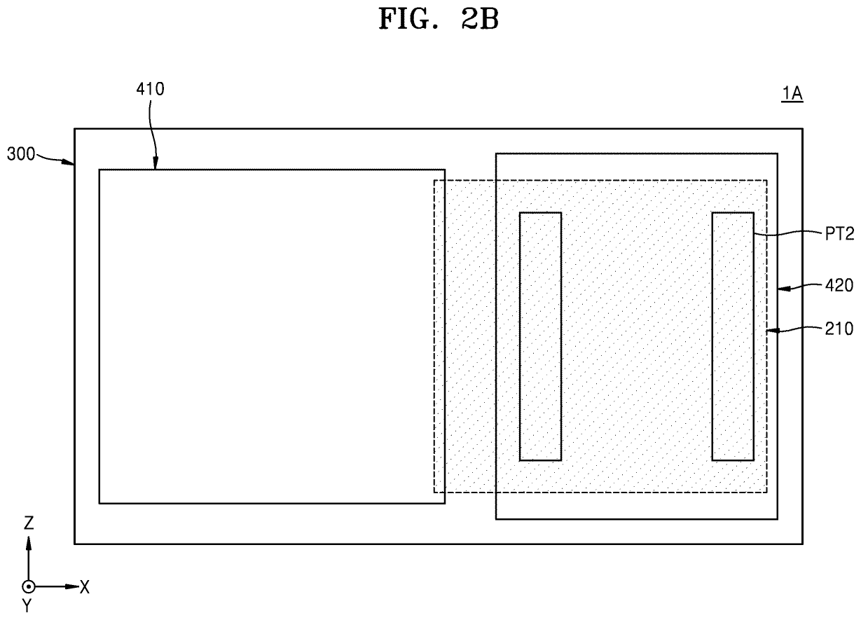

FIG. 2A is a cross-sectional view of a semiconductor package 1A according to embodiments. FIG. 2B is a plan view of a semiconductor package 1A according to embodiments. Descriptions that are not separately given may be substantially the same as those described above.

Referring to FIGS. 2A and 2B, a semiconductor package 1A may include a lower redistribution structure 100, a first semiconductor device 210 mounted on the lower redistribution structure 100, a plurality of conductive posts 220 laterally spaced apart from the first semiconductor device 210, an encapsulant 230 surrounding the side surface of the plurality of conductive posts 220 and the top surface and the side surface of the first semiconductor device 210, an upper redistribution structure 300 provided on the encapsulant 230 and electrically connected to the plurality of conductive posts 220, a second semiconductor device 410 provided on the upper redistribution structure 300, and a heat dissipation block 420 provided on the upper redistribution structure 300.

The heat dissipation block 420 may be laterally spaced apart from the second semiconductor device 410, and the heat dissipation block 420 may be provided on the upper redistribution structure 300. A heat transfer layer 422 may be arranged between the heat dissipation block 420 and the upper redistribution structure 300. The heat dissipation block 420 may include a block body 421 and a second protrusion PT2 protruding downward from a first block surface BS1 corresponding to a bottom surface of the heat dissipation block 420.

The second protrusion PT2 may protrude downward from the first block surface BS1 of the heat dissipation block 420. In embodiments, as shown in FIG. 2A, one shape of a vertical cross-section of the first block surface BS1 including the second protrusion PT2 may have a shape of a portion of a rectangular shape protruding downward. A plurality of second protrusions PT2 may be provided on the first block surface BS1, and each of the plurality of second protrusions PT2 may be positioned to be spaced apart from each other on the first block surface BS1.

Second concave portions CC2 may be provided on the top surface of the upper redistribution structure 300. The second concave portions CC2 may refer to grooves dug from the top surface of the upper redistribution structure 300 to the downside of the upper redistribution structure 300. The second concave portions CC2 may be provided on the top surface of the upper redistribution structure 300 to correspond to the second protruding portions PT2.

For example, as shown in FIG. 2B, the second protrusion PT2 may have a shape of a part of a rectangular shape protruding downward in a shape of a vertical cross section of the first block surface BS1, but may have a shape extending in one direction on the first block surface BS1. For example, as shown in FIG. 2B, two second protrusions PT2 extending in the same direction may be provided on the first block surface BS1. In addition, two or more second protrusions PT2 may be provided on the first block surface BS1.

Like the second protrusion PT2, a second concave portion CC2 corresponding to the second protrusion PT2 may extend in the same direction, and two second concave portions CC2 may be provided on the upper redistribution structure 300. The cross-sectional shape of the second concave portion CC2 may have a groove shape in which a part of a rectangular shape is removed from the top surface of the upper redistribution structure 300 to engage with the shape of the second protrusion PT2.

When two second protrusions PT2 are provided on the first block surface BS1, two second concave portions CC2 may be provided on the upper redistribution structure 300. Since the second protrusion PT2 and the second concave portion CC2 correspond to each other, the number of second protrusions PT2 may vary as necessary, but the number of second protrusions PT2 and the number of second concave portions CC2 may be the same. The shape of the cross section of the second concave portion CC2 may be larger than the shape of the cross section of the second protrusion PT2.

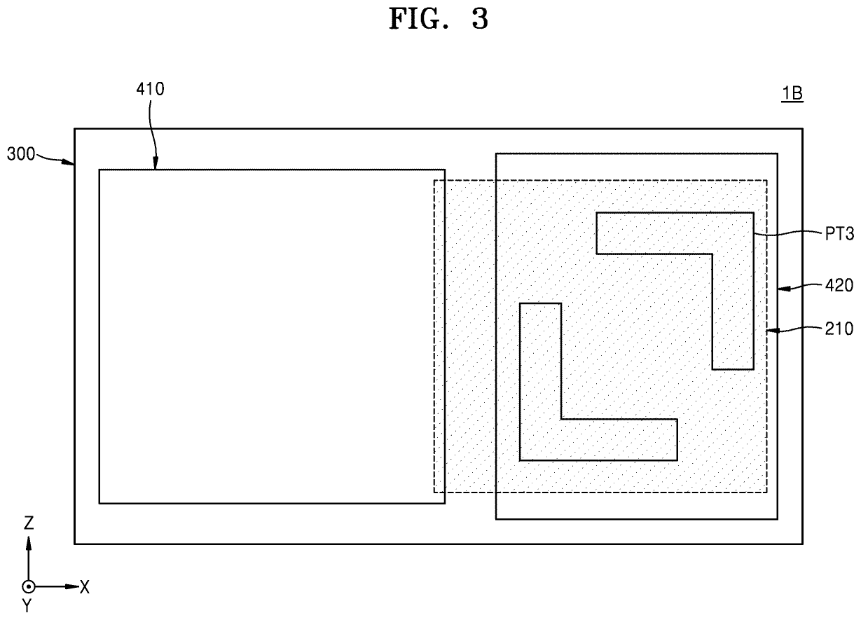

FIG. 3 is a plan view of a semiconductor package 1B according to embodiments. Descriptions that are not separately given may be substantially the same as those described above.

Referring to FIG. 3 together with FIG. 2A, third protrusions PT3 may be provided on the first block surface BS1. The third protrusions PT3 may have an L shape on the first block surface BS1. Like the third protrusions PT3, third concave portions corresponding to the third protrusions PT3 may have an L shape on the upper redistribution structure 300 and may have a complementary shape with respect to the third protrusions PT3. For example, the third protrusions PT3 having an L shape may be arranged to be similar to the outer edge of the first block surface BS1 of the heat dissipation block 420. That is, the bent portion of the third protrusions PT3 may face the vertices of the first block surface BS1, respectively, and two consecutive corners of the first block surface BS1 and the third protrusion PT3 having an L shape may be arranged to be parallel to each other.

As shown in FIG. 1A, the vertical cross-section of the third protrusion PT3 may have an elliptical shape in which the shape of the vertical cross-section of the first block surface BS1 including the third protrusion PT3 protrudes downward. Alternatively, as shown in FIG. 2A, the vertical cross-section of the third protrusion PT3 may have a shape of a portion of a rectangular shape in which the shape of the vertical cross-section of the first block surface BS1 including the third protrusion PT3 protrudes downward.

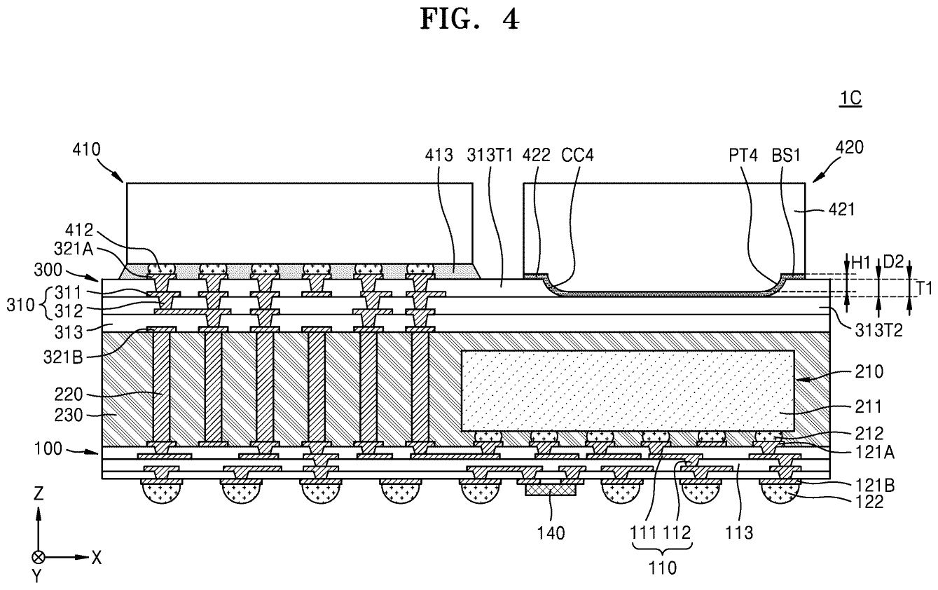

FIG. 4 is a cross-sectional view of a semiconductor package 1C according to embodiments. Descriptions that are not separately given may be substantially the same as those described above.

Referring to FIG. 4, a fourth protrusion PT4 may protrude downward from the first block surface BS1 of the heat dissipation block 420. In embodiments, the fourth protrusion PT4 may include a plane uniformly protruding downward from the first block surface BS1. That is, the fourth protrusion PT4 may have a shape in which all portions other than those adjacent to the outer edge of the bottom surface of the heat dissipation block 420 protrude downward. Accordingly, the shape of the vertical cross section of the fourth protrusion PT4 may include a planar shape.

A second depth D2, which is a depth at which a fourth concave portion CC4 is recessed based on the top surface of the upper redistribution structure 300, may be substantially equal to or less than a first thickness T1, which is a vertical thickness of the first upper redistribution insulating layer 313T1. A first height H1, which is a height to which the first protrusion PT1 protrudes from the first block surface BS1, may be greater than or substantially the same as a second depth D2 of the fourth concave portion CC4.

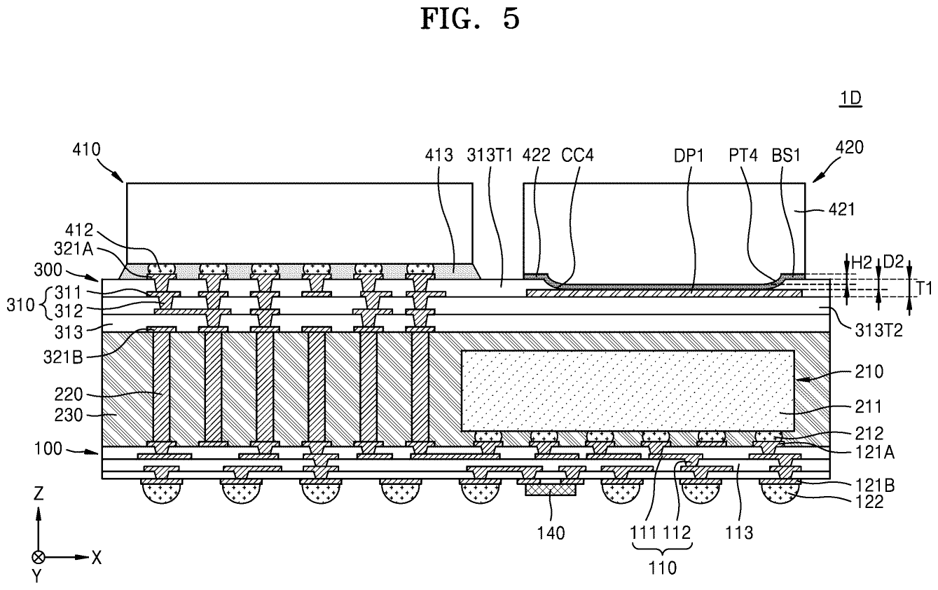

FIG. 5 is a cross-sectional view of a semiconductor package 1D according to embodiments. Descriptions that are not separately given may be substantially the same as those described above.

Referring to FIG. 5, a semiconductor package 1D may include a lower redistribution structure 100, a first semiconductor device 210 mounted on the lower redistribution structure 100, a plurality of conductive posts 220 laterally spaced apart from the first semiconductor device 210, an encapsulant 230 surrounding the side surface of the plurality of conductive posts 220 and the top surface and the side surface of the first semiconductor device 210, an upper redistribution structure 300 provided on the encapsulant 230 and electrically connected to the plurality of conductive posts 220, a second semiconductor device 410 provided on the upper redistribution structure 300, a heat dissipation block 420 provided on the upper redistribution structure 300, and a first dummy plate DP1 provided in the upper redistribution structure 300.

The first dummy plate DP1 may be provided between a plurality of upper redistribution insulating layers 313. For example, as shown in FIG. 5, the first dummy plate DP1 may be provided between a first upper redistribution insulating layer 313T1 located at the uppermost end of the upper redistribution insulating layer 313 and a second upper redistribution insulating layer 313T2. The first dummy plate DP1 may be formed together when a plurality of upper redistribution patterns 310 positioned between the first upper redistribution insulating layer 313T1 and the second upper redistribution insulating layer 313T2 are formed. Unlike the plurality of upper redistribution patterns 310 provided in the upper redistribution structure 300, the first dummy plate DP1 may have no electrical connection.

The fourth concave portion CC4 may be a groove extending from the top surface of the upper redistribution structure 300 to the first dummy plate DP1. That is, in the process of forming the fourth concave portion CC4, a portion of the first upper redistribution insulating layer 313T1 is removed, and since the first dummy plate DP1 is not removed, the fourth concave portion CC4 may be formed until the first dummy plate DP1 is reached. Thus, the second depth D2, which is the depth at which the fourth concave portion CC4 is recessed based on the top surface of the upper redistribution structure 300, may be less than the first thickness T1, which is the vertical thickness of the first upper redistribution insulating layer 313T1.

The fourth protrusion PT4 may have a complementary shape with respect to the fourth concave portion CC4 so that the fourth protrusion PT4 may be arranged in the fourth concave portion CC4. A portion of the fourth protrusion PT1 and a portion of the first dummy plate DP1 may be parallel to each other. A detailed description of the formation thereof is substantially the same as the description of the fourth protrusion PT4 of FIG. 4.

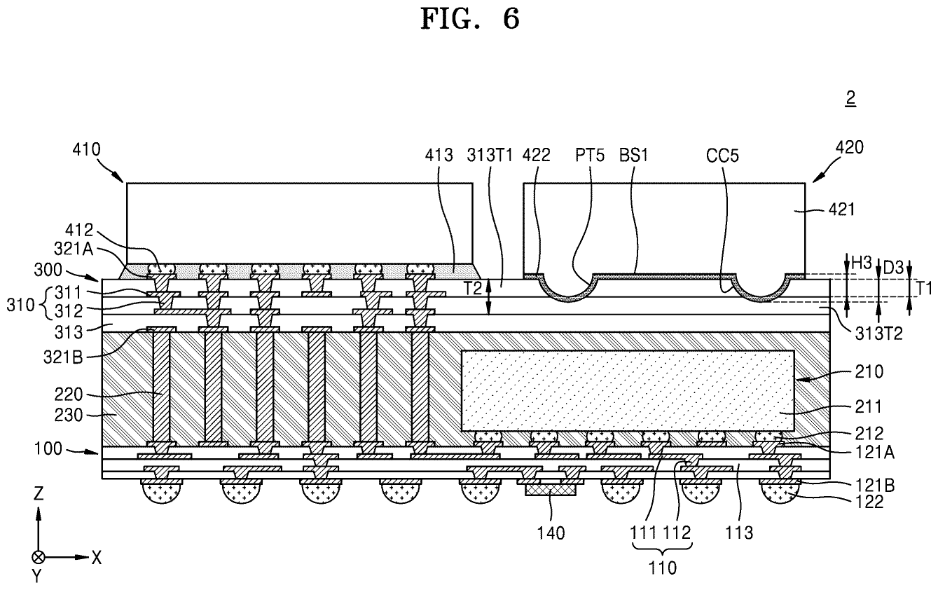

FIG. 6 is a cross-sectional view of a semiconductor package 2 according to embodiments. Descriptions that are not separately given may be substantially the same as those described above.

Referring to FIG. 6, the heat dissipation block 420 of the semiconductor package 2 may include a fifth protrusion PT5. The shape of the vertical cross-section of the first block surface BS1 including the fifth protrusion PT5 may have an elliptical shape protruding downward. However, a third height H3, which is a height to which the fifth protrusion PT5 protrudes from the first block surface BS1, may be greater than a first thickness T1, which is a thickness of the first upper redistribution insulating layer 313T1.

A fifth concave portion CC5 may have a shape complementary to that of the fifth protrusion PT5. That is, the shape of the vertical cross-section including the fifth concave portion CC5 of the upper redistribution structure 300 may be a shape dug inward in a shape of a portion of an ellipse. A third depth D3, which is a depth at which the fifth concave portion CC5 is recessed from the top surface of the upper redistribution structure 300, may be greater than the first thickness T1, which is a vertical thickness of the first upper redistribution insulating layer 313T1. The third depth D3 of the fifth concave portion CC5 may be equal to or less than the second thickness T2, which is a vertical thickness of the first upper redistribution insulating layer 313T1 and the second upper redistribution insulating layer 313T2. The second thickness T2 may mean a thickness of the uppermost two redistribution insulating layers among the plurality of upper redistribution insulating layers 313. A third height H3, which is a vertical height to which the fifth protrusion PT5 protrudes from the first block surface BS1, may be substantially the same as the third depth D3 of the fifth concave portion CC5.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first semiconductor device;
an encapsulant surrounding the first semiconductor device;
an upper redistribution structure provided on the encapsulant; and
a heat dissipation block provided on the upper redistribution structure, wherein
the heat dissipation block includes a first block surface facing a top surface of the upper redistribution structure,
the heat dissipation block includes a first protrusion on the first block surface,
a first concave portion corresponding to the first protrusion is provided on the top surface of the upper redistribution structure, and
the first protrusion is located in the first concave portion.

2. The semiconductor package of claim 1, wherein at least a portion of the heat dissipation block perpendicularly overlaps the first semiconductor device.

3. The semiconductor package of claim 1, wherein a first height, which is a height protruding from the first block surface of the first protrusion, is equal to or less than a first depth, which is a depth recessed downward from the top surface of the upper redistribution structure of the first concave portion.

4. The semiconductor package of claim 1, wherein
the upper redistribution structure includes a plurality of upper redistribution insulating layers,
a first depth of the first concave portion is equal to or less than a first thickness, which is a thickness of an uppermost first upper redistribution insulating layer among the plurality of upper redistribution insulating layers, and
the first depth is defined as a depth recessed downward from the top surface of the upper redistribution structure of the first concave portion.

5. The semiconductor package of claim 1, wherein
the upper redistribution structure includes a plurality of redistribution insulating layers,
a depth of the first concave portion is less than a second thickness, which is a thickness of two redistribution insulating layers positioned uppermost among the plurality of redistribution insulating layers,
the depth of the first concave portion is greater than a first thickness, which is a thickness of a first upper redistribution insulation layer positioned uppermost among the plurality of redistribution insulation layers, and
the depth of the first concave portion is defined as a depth recessed downward from the top surface of the upper redistribution structure of the first concave portion.

6. The semiconductor package of claim 1, wherein
the first protrusion is integrally formed with the heat dissipation block, and
the heat dissipation block includes at least one of aluminum (Al), copper (Cu), titanium (Ti), nickel (Ni), iron (Fe), cobalt (Co), palladium (Pd), platinum (Pt), gold (Au), lead (Pb), silver (Ag), carbon (C), tin (Sn), tungsten (W), and chromium (Cr).

7. The semiconductor package of claim 1, wherein
a plurality of the first protrusions are provided on the first block surface, and
a shape of a vertical cross-section of one of the plurality of the first protrusions is a portion of an oval.

8. The semiconductor package of claim 1, wherein the first protrusion extends in one direction on the first block surface and is linearly provided on the first block surface.

9. The semiconductor package of claim 1, wherein
a first dummy metal layer is included in the upper redistribution structure,
the first dummy metal layer is provided between a plurality of redistribution insulating layers provided in the upper redistribution structure,
the first concave portion is provided on the first dummy metal layer,
a heat transfer layer is provided between the first dummy metal layer and the heat dissipation block and between the heat dissipation block and the top surface of the upper redistribution structure, and
a portion of the first dummy metal layer and at least a portion of the first protrusion are parallel to each other.

10. The semiconductor package of claim 1, further comprising a second semiconductor device laterally spaced apart from the heat dissipation block and provided on the upper redistribution structure,
wherein the first semiconductor device includes a logic chip, and the second semiconductor device includes a memory chip.

11. A semiconductor package comprising:
a lower redistribution structure;
a first semiconductor device arranged on the lower redistribution structure;
a plurality of conductive posts laterally spaced apart from the first semiconductor device and provided on the lower redistribution structure;
an encapsulant surrounding the first semiconductor device and the plurality of conductive posts;
an upper redistribution structure provided on the encapsulant;
a heat dissipation block provided on the upper redistribution structure; and
a second semiconductor device laterally spaced apart from the heat dissipation block and arranged on the upper redistribution structure, wherein
the heat dissipation block includes a first block surface facing a top surface of the upper redistribution structure,
the heat dissipation block includes at least one first protrusion on the first block surface,
at least one first concave portion corresponding to the first protrusion is provided on the top surface of the upper redistribution structure, and
the first protrusion is located in the first concave portion.

12. The semiconductor package of claim 11, wherein
at least a portion of the heat dissipation block overlaps the first semiconductor device perpendicularly, and
the second semiconductor device overlaps at least a portion of the plurality of conductive posts perpendicularly.

13. The semiconductor package of claim 11, wherein
the upper redistribution structure includes a plurality of redistribution insulating layers,
a first depth of the first concave portion is equal to or less than a first thickness, which is a thickness of an uppermost first upper redistribution insulating layer among the plurality of redistribution insulating layers, and
the first depth of the first concave portion is defined as a depth recessed downward from the top surface of the upper redistribution structure of the first concave portion.

14. The semiconductor package of claim 11, further comprising a heat transfer layer disposed between the heat dissipation block and the top surface of the upper redistribution structure.

15. The semiconductor package of claim 11, wherein
the upper redistribution structure includes a plurality of redistribution insulating layers,
a depth of the first concave portion is less than a second thickness, which is a thickness of two redistribution insulating layers positioned uppermost among the plurality of redistribution insulating layers,
the depth of the first concave portion is greater than a first thickness, which is a thickness of a first upper redistribution insulation layer positioned uppermost among the plurality of redistribution insulation layers, and
the depth of the first concave portion is defined as a depth recessed downward from the top surface of the upper redistribution structure of the first concave portion.

16. The semiconductor package of claim 11, wherein
the first protrusion is integrally formed with the heat dissipation block, and
a vertical cross-section of the first protrusion has a rectangular shape.

17. The semiconductor package of claim 11, wherein a planar shape of the first protrusion on the first block surface of the heat dissipation block has an L shape.

18. The semiconductor package of claim 11, wherein
a plurality of redistribution insulating layers are provided on the upper redistribution structure,
a first dummy metal layer is provided in the plurality of redistribution insulating layers, and
at least a portion of the first dummy metal layer perpendicularly overlaps the first semiconductor device.

19. A semiconductor package comprising:
a lower redistribution structure;
a first semiconductor device arranged on the lower redistribution structure;
a plurality of conductive posts laterally spaced apart from the first semiconductor device and provided on the lower redistribution structure;
an encapsulant surrounding the first semiconductor device and the plurality of conductive posts;
an upper redistribution structure provided on the encapsulant;
a heat dissipation block provided on the upper redistribution structure; and
a second semiconductor device laterally spaced apart from the heat dissipation block and arranged on the upper redistribution structure, wherein
the heat dissipation block includes a first block surface facing a top surface of the upper redistribution structure,
the heat dissipation block includes at least one first protrusion on the first block surface,
at least one first concave portion corresponding to the first protrusion is provided on the top surface of the upper redistribution structure, the first protrusion is located in the first concave portion, a heat transfer layer is provided between the heat dissipation block and the top surface of the upper redistribution structure,
at least a portion of the heat dissipation block overlaps the first semiconductor device perpendicularly, the second semiconductor device overlaps at least a portion of the plurality of conductive posts perpendicularly,
the upper redistribution structure includes a plurality of redistribution insulating layers,
a first depth of the first concave portion is equal to or less than a first thickness, which is a thickness of an uppermost first upper redistribution insulating layer among the plurality of redistribution insulating layers,
a first height of the first protrusion is equal to or less than the first depth of the first concave portion,
the first depth of the first concave portion is defined as a depth recessed downward from the top surface of the upper redistribution structure of the first concave portion, the first height of the first protrusion is defined as a height of the first protrusion from the first block surface,
the first concave portion has a shape complementary to a shape of the first protrusion,
the first protrusion is integrally formed with the heat dissipation block, and a shape of the vertical cross-section of the first protrusion is a portion of an oval.

20. The semiconductor package of claim 19, wherein
a planar shape of the first block surface is a rectangular shape,
a plurality of the first protrusions are provided on the first block surface,
the plurality of the first protrusions are spaced apart from each other and are adjacent to vertices of the rectangular shape of the first block surface,
the first height of the first protrusion is about 5μm to about 20μm,
the first semiconductor device includes a logic chip, and the second semiconductor device includes a memory chip.
